(19) United States
(12) Patent Application Publication
(10) Pub. No.: US 2003/0015803 A1
(43) Pub. Date: Jan. 23, 2003

(54) High-density multichip module and method for manufacturing the same

(75) Inventor: Dieter Prietzsch, Berlin (DE)

Correspondence Address: HENRY M FEIEREISEN, 350 FIFTH AVENUE, SUITE 3220, NEW YORK, NY, 10118, US

(73) Assignee: OPTOSYS TECHNOLOGIES GMBH

(21) Appl. No.: 10/196,094

(22) Filed: Jul. 16, 2002

(30) Foreign Application Priority Data
Jul. 20, 2001 (DE) 101 36 655.8

(51) Int. Cl. H01L 23/48

(52) U.S. Cl. 257/777; 438/109; 257/686

(57) ABSTRACT

Multichip modules with stacked semiconductor chips, in particular non-volatile memory chips,.are provided that have peripherally arranged bonding pads. The semiconductor chips have identical dimensions and are spaced apart by spacers of smaller dimensions that prevent the chip from directly contacting each other and allow wire-bonding of each of the stacked chips to the bonding pads. The chips are preferably nude chips. A method for mounting the chips is also disclosed.

### CROSS-REFERENCES TO RELATED APPLICATIONS

This application claims the priority of German Patent Application Serial No. DE 101 36 655.8, filed Jul. 20, 2001, pursuant to 35 U.S.C. 119(a)-(d), the subject matter of which is incorporated herein by reference.

### BACKGROUND OF THE INVENTION

The present invention relates to memory modules with semiconductor chips arranged in chip-on-board (COB) structure, and more particularly to memory modules with stacked non-volatile memory chips having peripherally arranged bonding pads. The invention also relates to a method for mounting the memory chips.

The continued improvements of portable computers, the rapid development in the mobile telephone industry, in particular the development of digital photography, require more powerful and sophisticated computing and memory modules. Demand for memory modules with high storage capacity is particularly driven by the need for additional functions in the mobile communication sector.

Miniaturization also calls for an increase in the packing density of memory chips and other electronic components, such as controllers.

DE 197 28 953 A1 discloses a manufacturing method and a layout for a multi-chip module. The chips are arranged in a defined pattern on the circuit board and then bonded on the same side. The chips are then covered with a low-viscosity epoxy introduced into the space between the chips. Thereafter, a material is introduced lengthwise between the rows, whereafter the valves of the material application device are closed, whereby the device returns to the starting point of the module. A first ring is then placed about the outer periphery of the chip region. A second ring is placed in spaced-apart disposition from the first ring, whereafter a sealing compound is applied in a meander pattern from the outside of the narrow side of the modules in the direction of the opposite outside edge. The same number of chips can be arranged on both sides of the circuit board in a defined pattern.

DE 197 47 177 A1 discloses a housed component, in particular a stackable housed electronic component, as well as a method for manufacturing the same. This component has a substrate with a first region, a second region and a flexible region connecting the first region and the second region. At least one component with contacts is arranged on the first region of substrate. The second region is then flipped over the first region by bending the flexible region, so that the first region and the second region are arranged opposite one another and enclose the at least one component. The external connections of the at least one component are routed to a major exterior surface of the first and/or second region. The enclosed components can be stacked and interconnected with one another by solder bumps arranged on the major exterior surfaces of the first and/or second regions.

U.S. Pat. No. 5,910,682 discloses a semiconductor chip stack package with a plurality of semiconductor chips. Each chip has a plurality of chip pads formed on an upper surface and a plurality of wires respectively coupling a corresponding one of the plurality of chip pads to an edge portion of the semiconductor chip. A package body is formed by stacking the plurality of semiconductor chips one over another using an adhesive medium. A tab tape adhesively attaches to a second side surface of the package body, and a heat sink adhesively attaches to each of a lower, upper and first side surfaces of the package body. A plurality of solder balls is formed on a lower surface of the tab tape for coupling to an external medium, such as a printed circuit board. The stack package facilitates external emission of the heat generated by the semiconductor chips to prevent the stack package reliability from deterioration. This chips are here stacked perpendicular to the plane of the printed circuit board, which makes handling difficult.

GB 2 344 217 A1 discloses a multichip module with stacked semiconductor chips. The chips are arranged in direct superposition on a substrate with wire bonding pads. When both the bottom chip and the upper chip(s) are connected to the substrate via wire bonds, then the upper chip(s) need to be smaller in size than the bottom chip, which reduces the storage capacity of the upper chip(s) and hence also the storage capacity of the module. For chips of equal size, wire bonds can typically not simultaneously formed for the bottom chip and the upper chip(s). Instead, the bottom chip can be connected to the pads on the substrate by solder bumps wherein the top chip is connected to the substrate via wire bonds; alternatively, the upper chip can be connected to the lower chip by solder bumps which is then connected to the substrate via wire bonds.

The storage capacity of the flash card is limited by the particular chip version. In particular, packaged flash components such as Thin-Small-Outline-Packages (TSOP) or similar packages, can only be arranged within the geometric surface area of the board.

It would therefore be desirable and advantageous to provide an improved module with mounted semiconductor chips, in particular a module with versatile non-volatile memory chips in COB construction, such as chips with a large storage capacity, and to provide an assembly process for the module.

### SUMMARY OF THE INVENTION

The present invention is directed to increasing the storage density of memory modules. For example, it is possible by employing bare dies to integrate an additional number of chips by stacking the chips in layers and to thereby further increase the storage capacity of a flash card. It is also possible to stack other components, for example controllers. This arrangement can be applied to compact flash cards which have a microcontroller and a number of flash components, for example flash chips, that provide the desired storage capacity.

According to one aspect of the invention, a multichip module includes a board with bonding pads arranged in a peripheral region of the board, a first chip and a second chip implemented as nude chips with substantially identical dimensions; and a spacer having at least one linear dimension that is smaller than a linear dimension of the first and second chips. The spacer is disposed between the first and second chip to provide a gap between the first and second chips.

The present invention makes it possible to stack a number of, for example, n additional chips and/or other components by using the unused space in the z-direction perpendicular to the plane of the board, thereby increasing the storage capacity n-fold. For example, so-called “nude chips” can be stacked in three, four and even more layers or planes in a “sandwich configuration”. The term “sandwich configuration” is meant to convey that the nude chips are not stacked in direct contact with one another. This requires a certain design which also takes into account the layout of the bond wires, so that the functionality of the device is not diminished.

A stacked arrangement of chips, in particular with respect to forming electrical connections, can be realized by placing a spacer between two chip planes and connecting the superpositioned chips and the spacer with an adhesive joint. The length of the spacer is determined by the desired wire bond connections. To prevent damage to the bond wires, the spacer is preferably shorter on the sides that face the bonding pads.

Is also possible to modify the adhesive. For example, the adhesive can also be applied to the underside of the spacer or the chip. This could prevent possible damage to the active structures of the chip. The adhesive joint can also be formed, for example, by a foil that is coated on both sides with an adhesive and/or by an electrically insulating plate that can be made of plastic, ceramic or glass.

The first chip and the second chip can further include contact pads, with the contact pads being connected with corresponding bonding pads by a bonding wire, wherein the bonding pads are arranged in a pattern to prevent electrical contact between exposed surfaces of different bonding wires. The loop height of the bonding wire has advantageously a maximum value of 100 μm above a major surface of the first and second chip. This prevents the subsequently mounted chip from touching the bonding wire.

According to another aspect of the invention, a method for producing multichip modules includes arranging on a board bonding pads in a peripheral region of the board, mounting a first chip implemented as a nude chip on the board, said first chip having a first linear dimension, mounting on the first chip a spacer having at least one linear dimension that is smaller than the first linear dimension, mounting on the spacer a second chip having a linear dimension substantially identical to the linear dimension of the first chip, said spacer defining a gap between the first and second chip.

An adhesive is applied on the board before mounting the first chip, wherein the adhesive is preferably an electrically insulating and thermally conducting material. After the first chip has been mounted, a bonding wire can be attached between a connection pad disposed on the first chip and a corresponding bonding pad. Additional chips can be stacked on the second chip by the same process, with interposed spacers.

The first and second chips can each include a plurality of chips defining corresponding chip planes. A gap of approximately 0.1 to 0.2 mm can be formed between adjacent chips in a corresponding chip plane, and the gap can be filled with a hardenable epoxy adhesive. A functional test can be performed after each chip or after each chip plane has been mounted.

The signals required for operating the flash component are all identical, except for /CE, meaning that the respective chip is activated via the corresponding /CE(n) signal, whereby n corresponds to the number of chips.

A contact pattern can be formed on the board for the purpose of separating in a functional test those chips that fail the test.

With the aforedescribed arrangement which takes advantage of the unused spaced along the z-axis, nude chips and/or other components can be arranged on a board, which can significantly increase the storage capacity and/or the functionality without requiring additional surface area on the board.

### BRIEF DESCRIPTION OF THE DRAWING

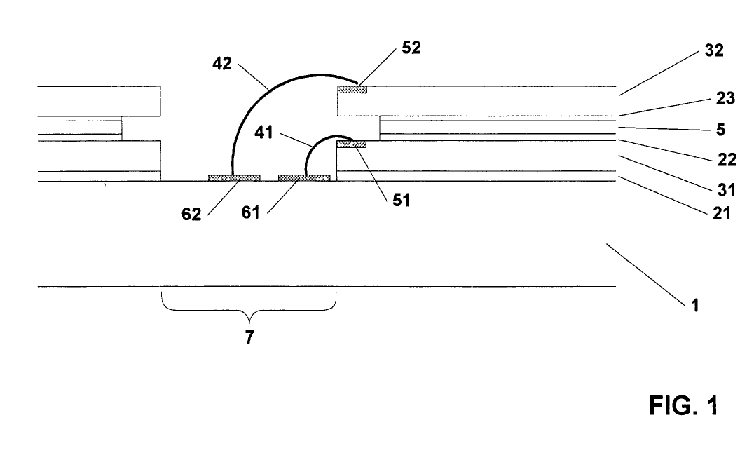

Other features and advantages of the present invention will be more readily apparent upon reading the following description of currently preferred exemplified embodiments of the invention with reference to the accompanying drawing, in which the sole FIG. 1 shows a vertical cross-section through a portion of a multichip module.

### DETAILED DESCRIPTION OF PREFERRED EMBODIMENTS

The device and method described herein are directed to memory modules with semiconductor chips arranged in chip-on-board (COB) structure, and more particularly to memory modules with stacked non-volatile memory chips having peripherally arranged bonding pads.

A board 1, for example a printed circuit board, has formed thereon bonding pads 61, 62 arranged in a pattern. Those skilled in the art will understand that bonding pads can be connected to interconnects formed on the board for connection to other bonding pads or to external connector pads. A chip 31 can be bonded to a major surface of the board 1, for example, by applying an adhesive 21 or an adhesive foil 21 in a region of the major surface. The chip 31 can have contact pads 51 on one of its major surfaces which can be electrically connected to the bonding pad 61 on the board 1 in a conventional manner by a bond wire 41. Thereafter, the functionality of the mounted chip 31 can be tested.

Subsequently, an adhesive layer 22, preferably in form of an insulating thermal epoxy, is applied to surface of the chip 31. A spacer 5 is then applied over the entire adhesive joint 22, covering the joint 22. The spacer 5 can be flexible or rigid and can be formed of a foil or a plate, such as a plastic, ceramic or glass plate. Another adhesive joint 23 is then applied to the spacer 5 for mounting the chip 32 belonging to the next chip plane. As described above with reference to the chip 31, the chip 32 can have contact pads 52 on one of its major surfaces which can be electrically connected to the bonding pad 62 on the board 1 in a conventional manner by a bond wire 42. Thereafter, the functionality of the mounted chip 32 can be tested. This process can be repeated with other chips to be stacked on top of chip 32.

The dimensions of the bonding pads of the board should be defined so that the stacked wire bonds can be formed sequentially on the bonding pad, without interfering with one another. To prevent damage to the bonding wires, the loop height of the bonding wire has preferably a maximum value of 100 μm above a major surface of a chip. Only the chip-specific signal /CE is supplied separately to each chip. Also, a gap 7 of 0.1 to 0.2 mm width is advantageously formed between adjacent chips in a chip plane for access to and mechanical support of the bonding wires. The gap 7 can then be filled with a hardenable epoxy material.

While the invention has been illustrated and described as embodied in a high-density multichip module and method for manufacturing the same, it is not intended to be limited to the details shown since various modifications and structural changes may be made without departing in any way from the spirit of the present invention. The embodiments were chosen and described in order to best explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and their equivalents:

What is claimed is:

1. A multichip module, comprising
a board having bonding pads arranged in a peripheral region of the board,
a first chip and a second chip implemented as nude chips with substantially identical dimensions, and
a spacer having at least one linear dimension that is smaller than a linear dimension of the first and second chips,
said spacer disposed between the first and second chip to provide a gap between the first and second chips.

2. The multichip module of claim 1, further including a plurality of adhesive joints disposed between the first chip and the spacer, and between the spacer and the second chip.

3. The multichip module of claim 1, wherein said shorter dimension of the spacer is in a direction on the board that faces the bonding pads.

4. The multichip module of claim 1, wherein the spacer is in the form of a foil or an electrically insulating plate.

5. The multichip module of claim 4, wherein the plate is made of plastic, ceramic or glass.

6. The multichip module of claim 1, wherein the first chip and the second chip further comprise contact pads, said contact pads connected with corresponding bonding pads by a bonding wire, wherein the bonding pads are arranged in a pattern to prevent electrical contact between exposed surfaces of different bonding wires.

7. The multichip module of claim 6, wherein a loop height of the bonding wire has a maximum value of 100 μm above a major surface of the first and second chip.

8. The multichip module of claim 6, wherein the chips are flash chips, the module further comprising a controller, peripheral elements, and connectors.

9. A method for producing multichip modules, comprising the steps of:
arranging on a board bonding pads in a peripheral region of the board,
mounting a first chip implemented as a nude chip on the board, said first chip having a first linear dimension,
mounting on the first chip a spacer having at least one linear dimension that is smaller than the first linear dimension,
mounting on the spacer a second chip having a linear dimension substantially identical to the linear dimension of the first chip,
said spacer defining a gap between the first and second chip.

10. The method of claim 9, further including applying an adhesive on the board before mounting the first chip.

11. The method of claim 10, wherein the adhesive is an electrically insulating and thermally conducting material.

12. The method of claim 9, and further including attaching, after the first chip has been mounted, a bonding wire between a connection pad disposed on the first chip and a corresponding bonding pad, and repeating said attaching for the second chip and subsequent chips stacked on the second chip.

13. The method of claim 9, and further comprising the steps of providing a plurality of first chips, said plurality of first chips defining a first chip plane, and providing a plurality of second chips, said plurality of second chips defining a second chip plane, placing said second chip plane on the first chip plane in such a way that a gap of approximately 0.1 to 0.2 mm is formed between adjacent chips in a corresponding chip plane, and filling the gap with a hardenable epoxy adhesive.

14. The method of claim 9, and further comprising the step of performing a functional test after each chip has been mounted.

15. The method of claim 9, and further comprising the step of repeating mounting another spacer and mounting another second chip for form an n-layer stack, with n being greater than 2.
